(19) United States
(12) Patent Application Publication
(10) Pub. No.: US 2026/0204519 A1
(43) Pub. Date: Jul. 16, 2026

(54) SYSTEMS AND METHODS FOR USING A SQUARE-SHAPED PULSE SIGNAL TO INCREASE A RATE OF PROCESSING A SUBSTRATE

(71) Applicant: Lam Research Corporation, Fremont, CA (US)

(72) Inventors: Alexei M. Marakhtanov, Albany, CA (US); Bing Ji, Pleasanton, CA (US); Ranadeep Bhowmick, San Jose, CA (US); Felix Leib Kozakevich, Sunnyvale, CA (US); John P. Holland, San Jose, CA (US)

(21) Appl. No.: 19/136,260

(22) PCT Filed: Dec. 8, 2023
(86) PCT No.: PCT/US23/83215

§ 371 Date: Jun. 5, 2025

Related U.S. Application Data
(60) Provisional application No. 63/432,357, filed on Dec. 13, 2022.

(51) Int. Cl. H01J 37/32; H10P 34/40

(52) U.S. Cl. CPC H01J 37/32183; H01J 37/32146; H10P 34/40

(57) ABSTRACT

Systems and methods for increasing a rate of processing a substrate using a square wave signal are described. One of the methods includes generating, by a low frequency (LF) radio frequency (RF) pulse generator, the square wave signal. The method further includes generating, by a high frequency (HF) RF signal generator, a sinusoidal RF signal and supplying the square wave signal to a filter coupled to an electrode of a plasma chamber. The method includes supplying the sinusoidal RF signal to an impedance matching circuit that is coupled to the electrode. The operation of supplying the square wave signal reduces power reflected towards the HF RF signal generator from the plasma chamber. The reduction in the power reflected towards the HF RF signal generator increases the rate of processing the substrate.

### FIELD

The present embodiments relate to systems and methods for using a square-shaped pulse signal for increasing a rate of processing a substrate.

### BACKGROUND

In a plasma tool, a radio frequency (RF) generator is coupled to a match network. The match network is coupled to a plasma chamber. A semiconductor wafer is placed in the plasma chamber. The RF generator generates an RF signal and sends the RF signal to the matching network. The matching network outputs a modified signal based on the RF signal and sends the modified signal to the plasma chamber to process the semiconductor wafer. The RF generator is controlled to increase a rate of processing the semiconductor wafer. However, sometimes, the increase in the rate is not achieved.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Embodiments of the disclosure provide systems, apparatus, methods and computer programs for using a square-shaped pulse signal for increasing a rate of processing a substrate. It should be appreciated that the present embodiments can be implemented in numerous ways, e.g., a process, an apparatus, a system, a device, or a method on a computer readable medium. Several embodiments are described below.

In one embodiment, a method for increasing a rate of processing a substrate using a square wave signal is described. The method includes generating, by a low frequency (LF) radio frequency (RF) pulse generator, the square wave signal. The method further includes generating, by a high frequency (HF) RF signal generator, a sinusoidal RF signal and supplying the square wave signal to a filter coupled to an electrode of a plasma chamber. The method includes supplying the sinusoidal RF signal to an impedance matching circuit that is coupled to the electrode. The operation of supplying the square wave signal reduces power reflected towards the HF RF signal generator from the plasma chamber. The reduction in the power reflected towards the HF RF signal generator increases the rate of processing the substrate.

In an embodiment, a controller for increasing a rate of processing a substrate using a square wave signal is described. The controller includes a processor that controls an LF RF pulse generator to generate the square wave signal and supply the square wave pulse signal to a filter. The filter is coupled to an electrode of a plasma chamber. The processor further controls an HF RF signal generator to generate a sinusoidal RF signal and supply the sinusoidal RF signal to an impedance matching circuit. The impedance matching circuit is coupled to the electrode. The LF RF pulse generator is controlled to reduce power reflected towards the HF RF signal generator from the plasma chamber. The reduction in the power reflected towards the HF RF signal generator increases the rate of processing the substrate. The controller further includes a memory device coupled to the processor.

In one embodiment, a system for increasing a rate of processing a substrate using a square wave signal is described. The system includes an LF RF pulse generator that generates the square wave signal. The system further includes an HF RF signal generator that generates a sinusoidal RF signal. The system also includes a filter coupled to the LF RF pulse generator to receive the square wave signal and a plasma chamber having an electrode coupled to the filter. The system includes an impedance matching circuit between the HF RF signal generator and the electrode of the plasma chamber. The impedance matching circuit receives the sinusoidal RF signal. The LF RF pulse generator reduces power reflected towards the HF RF signal generator from the plasma chamber. The reduction in the power reflected towards the HF RF signal generator increases the rate of processing the substrate.

Several advantages of the herein described systems and methods include increasing the rate of processing the substrate. An HF RF signal generator is used with an LF RF pulse generator instead of an LF RF signal generator. The LF RF pulse generator generates a square wave signal. During each cycle of a clock signal, the square wave signal has a positive potential short pulse followed by a square-shaped negative potential, which may also include a series of micro pulses. The series of micro pulses is sometimes referred to herein as a flat negative square pulse. The flat negative square pulse creates stability, such as stability in a voltage and thickness, in a plasma sheath. Due to the stable sheath voltage and thickness, there is less change in plasma impedance, seen by the LF RF pulse generator and the HF RF signal generator. The high frequency of the HF RF signal generator is tuned more quickly and accurately when the change in impedance is less. Because the high frequency is tuned more quickly and accurately, the rate of processing the substrate increases.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1 is a diagram of an embodiment of a system for generating a square wave signal.

FIG. 2A is a graph to illustrate an embodiment of a clock signal.

FIG. 2B is a graph to illustrate embodiments of high frequency supplied power and high frequency reflected power during each cycle of the clock signal.

FIG. 2C is a graph to illustrate a voltage of the square wave signal that is generated by a low frequency (LF) radio frequency (RF) pulse generator versus time.

FIG. 2D is a graph of an embodiment of a voltage signal representing a voltage a bottom plasma sheath.

FIG. 3 is an embodiment of LF RF pulse generator.

FIG. 4A is a graph to illustrate that a greater amount of power is reflected towards a high frequency (HF) RF signal generator when an LF RF signal generator is used compared to when the LF RF pulse generator is used.

FIG. 4B is a graph to illustrate that a lesser amount of power is reflected towards the HF RF signal generator when the LF RF pulse generator is used compared to when the LF RF signal generator is used.

FIG. 5 is a graph to illustrate forward and reflected powers of an LF RF signal.

FIG. 6 is a diagram of an embodiment of a system to illustrate use of the HF RF signal generator with the LF RF signal generator and to illustrate that the rate of processing a substrate increases when the LF RF pulse generator is used.

### DETAILED DESCRIPTION

The following embodiments describe systems and methods for using a square-shaped pulse signal to increase a rate of processing a substrate. It will be apparent that the present embodiments may be practiced without some or all of these specific details. In other instances, well known operations have not been described in detail in order not to unnecessarily obscure the present embodiments.

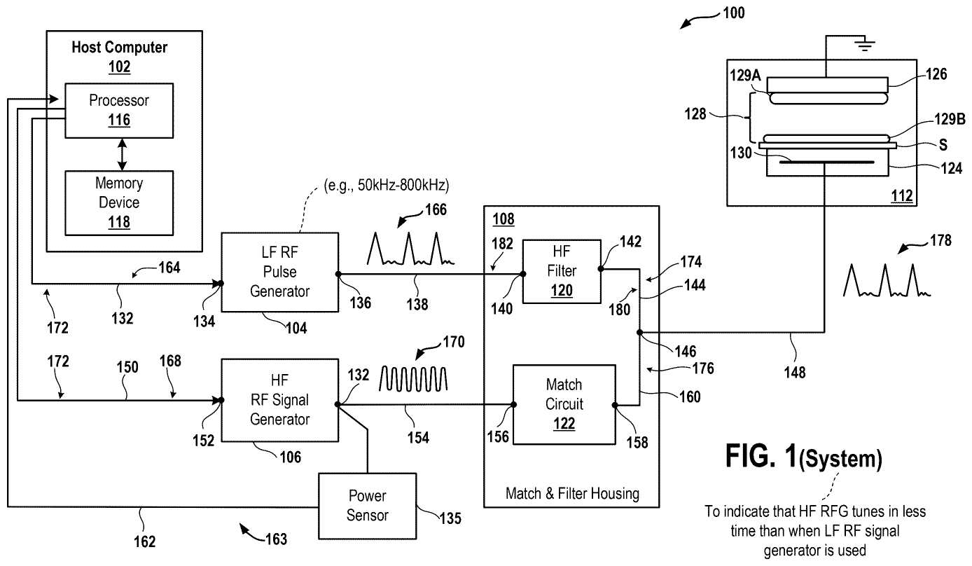

FIG. 1 is a diagram of an embodiment of a system 100 for generating square waves. The system 100 includes a host computer 102, a low frequency (LF) radio frequency (RF) pulse generator 104, a high frequency (HF) RF signal generator 106, a match and filter housing 108, and a plasma chamber 112. Examples of the host computer 102 include a desktop computer, a laptop computer, a tablet, a smart phone, and a controller. The host computer 102 includes a processor 116 and a memory device 118. As an example, a processor, as described herein, can be an application specific integrated circuit (ASIC), a central processing unit (CPU), a field programmable gate array (FPGA), a programmable logic device (PLD), an integrated controller, or a microcontroller. Examples of a memory device, as used herein, include a read-only memory (ROM) and a random access memory (RAM). To illustrate, the memory device is a flash memory or a redundant array of independent discs (RAID). The processor 116 is coupled to the memory device 118.

An example of the LF RF pulse generator 104 is a machine that generates multiple high-voltage nanosecond pulses periodically. To illustrate, the LF RF pulse generator is a nanosecond pulser. Each high-voltage nanosecond pulse is sometimes referred to herein as a sub-pulse. Examples of low frequency include frequencies ranging from and including 10 kilohertz (kHz) to 800 kHz. To illustrate, the low frequency is a baseline frequency of 400 kHz. To further illustrate, a frequency of operation of the LF RF pulse generator 104 is 400 kHz.

Examples of the high frequency include frequencies ranging from and including 13 megahertz (MHz) to 120 MHz. For example, the high frequency is a baseline frequency of 13.56 MHz or 27 MHz or 40 MHz or 60 MHz or 100 MHz. To illustrate, a frequency of operation of the HF RF signal generator 106 is 60 MHz. The high frequency is greater than the low frequency. For example, the low frequency is 400 kHz and the high frequency is 60 MHz. As another example, the low frequency is 100 kHz and the high frequency is 60 MHz. An example of the plasma chamber 112 is a capacitively-coupled (CCP) plasma chamber.

The match and filter housing 118 includes an HF filter 120 and a match circuit 122. An example of the HF filter 120 includes an inductor. As another example, the HF filter 120 is not an impedance matching circuit. To illustrate, the HF filter 120 does not match an impedance of a load coupled to an output 142 of the HF filter 120 with an impedance of a source coupled to an input 140 of the HF filter 120. An example of the load coupled to the output 142 includes a combination of an RF connection 144, an output connection 146, an RF transmission line 148, and the plasma chamber 112. An example of the source coupled to the input 140 includes an RF cable 138 and the LF RF pulse generator 104. Another example of the HF filter 120 includes an inductor that is coupled in parallel to a capacitor. Examples of the match circuit 122 include an impedance matching circuit and an impedance matching network. To illustrate, the impedance matching circuit or the impedance matching network has a branch circuit, which includes multiple circuit components, such as capacitors, inductors, and resistors, coupled to each other. To illustrate, two of the circuit components of the match circuit 122 are coupled to each other in a series or in parallel.

The plasma chamber 112 includes a substrate support 124, such as an electrostatic chuck (ESC). The plasma chamber 112 further includes an upper electrode 126 that is located above the substrate support 124 to form a gap 128 between the upper electrode 126 and the substrate support 124. The upper electrode 126 faces the substrate support 124 and is coupled to a ground potential. A lower electrode 130, embedded within the substrate support 124, is made from a metal, such as aluminum or an alloy of aluminum. The substrate support 124 is made from the metal and from a ceramic, such as aluminum oxide (Al₂O₃). The upper electrode 126 is fabricated from the metal.

The system 100 further includes a power sensor 135, which is coupled to an output 132 of the HF RF signal generator 106. Examples of the power sensor 135 include a sensor that measures delivered power at the output 132.

The processor 116 is coupled via a transfer cable 132 to an input 134 of the LF RF pulse generator 104. An example of a transfer cable includes a cable that allows for a serial transfer of data, or a parallel transfer of data, or a transfer of data via a universal serial bus (USB). The LF RF pulse generator 104 has an output 136 that is coupled via the RF cable 138 to the input 140 of the HF filter 120. For example, the RF cable 138 is coupled to a first end of the inductor of the HF filter 120. As an example, an RF cable includes an RF wire and an RF sheath that surrounds the RF wire.

The HF filter 120 has the output 142 that is coupled via the RF connection 144 to the output connection 146 of the match and filter housing 108. For example, a second end of the inductor of the HF filter 120 is coupled to the RF connection 144. An example of an RF connection, as used herein, is an RF strap or an RF cable. An example of the output connection 146 is a soldering between the RF connection 144 and an RF connection 160. Another example of the output connection 146 is a fastener, such as a screw, and a bolt that connects the RF connections 144 and 160. The output connection 146 is coupled via the RF transmission line 148 to the lower electrode 130. As an example, the RF transmission line 148 includes an RF rod, an insulator material, an RF sheath, and one or more RF straps. The insulator material is located between the RF rod and the RF sheath. The insulator material surrounds the RF rod and the RF sheath surrounds the insulator material. In the example, the RF rod is coupled to the output connection 146. Also, the RF rod is coupled to the output connection 146 via one of the one or more RF straps. The RF rod is coupled to the lower electrode 130.

The processor 116 is also coupled via a transfer cable 150 to an input 152 of the HF RF signal generator 106. The output 132 of the HF RF signal generator 106 is coupled via an RF cable 154 to an input 156 of the match circuit 122. For example, a first end of the branch circuit is coupled to the RF cable 154. An output 158 of the match circuit 122 is coupled via the RF connection 160 to the output connection 146. For example, a second end of the branch circuit is coupled to the RF connection 160. The power sensor 135 is coupled via a transfer cable 162 to the processor 116.

The processor 116 generates a recipe signal 164 and sends the recipe signal 164 via the transfer cable 132 and the input 134 to the LF RF pulse generator 104. As an example, the recipe signal 164 includes information, such as a pulse width and a sub-pulse width of a square wave signal 166 to be generated by the LF RF pulse generator 104. As an example, the square wave signal 166 is not a sinusoidal signal and has the low frequency. In the example, an envelope, such as a power level, of the sinusoidal signal is constant or substantially constant. For example, the power level has power amounts within a predetermined range, such as within ±10% from each other. To illustrate, the square wave signal has multiple sub-pulses that repeat periodically and each sub-pulse has the sub-pulse width. Also, in the illustration, the square wave signal has RF voltage ringing. In the illustration, each sub-pulse has a rectangular envelope or a square envelope and the RF voltage ringing is noise, such as a series of micro pulses, that immediately follows the sub-pulse. Further, in the illustration, an envelope of the sub-pulse is greater than an envelope of the RF voltage ringing by a predetermined amount, such as greater than 100%. To further illustrate, a maximum amplitude of the sub-pulse is more than double a maximum amplitude of the RF voltage ringing. The pulse width and the sub-pulse width are further described below. The pulse width provides the low frequency of the square wave signal 166. For example, the low frequency is an inverse of the pulse width.

As an example, the information within the recipe signal 164 does not include a power level, such as a maximum power amplitude, of the square wave signal 166. Rather, in the example, the power level of the sub-pulses of the square wave signal 166 is provided by the sub-pulse width. To illustrate, the greater the sub-pulse width, the lower the power level, and the lower the sub-pulse width, the higher the power level. As an example, the information within the recipe signal 164 is received from a user via an input device that is coupled to the processor 116. Examples of the input device include a keyboard, a mouse, a stylus, and a keypad. An example of a power level is a maximum amplitude or a peak-to-peak amplitude.

Moreover, the processor 116 generates a recipe signal 168 and sends the recipe signal 168 via the transfer cable 150 and the input 152 to the HF RF signal generator 106. As an example, the recipe signal 168 includes information, such as the high frequency and a power level, of an RF signal 170 to be generated by the HF RF signal generator 106. The RF signal 170 has the high frequency.

Upon receiving the recipe signal 164, a processor of the LF RF pulse generator 104 stores the information within the recipe signal 164 in a memory device of the LF RF pulse generator 104. The processor of the LF RF pulse generator 104 is coupled to the memory device of the LF RF pulse generator 104 and the processor and the memory device are parts of a controller of the LF RF pulse generator 104.

Similarly, upon receiving the recipe signal 168, a processor of the HF RF signal generator 106 stores the information within the recipe signal 168 in a memory device of the HF RF signal generator 106. The processor of the HF RF signal generator 106 is coupled to the memory device of the HF RF signal generator 106.

Moreover, the processor 116 generates and sends a trigger signal 172 via the transfer cable 164 and the input 134 to the processor of the LF RF pulse generator 104. Also, the trigger signal 172 is sent from the processor 116 via the transfer cable 150 and the input 152 to the processor of the HF RF signal generator 106. For example, the processor 116 sends the trigger signal 172 to both the LF RF pulse generator 104 and the HF RF signal generator 106 simultaneously.

Upon receiving the trigger signal 172, the processor of the LF RF pulse generator 104 accesses the information stored within the memory device of the LF RF pulse generator 104, and controls multiple signal components of the LF RF pulse generator 104 based on the information to generate the square wave signal 166. For example, the square wave signal 166 is generated to have the pulse width and the sub-pulse width received within the recipe signal 164 from the processor 116. The signal components of the LF RF pulse generator 104 are further described below. An example of the square wave signal 166 is a signal having multiple sub-pulses, such as square pulses, that repeat periodically according to the pulse width. Each square pulse has the sub-pulse width.

In a similar manner, in response to receiving the trigger signal 172, the processor of the HF RF signal generator 106 accesses the information stored within the memory device of the HF RF signal generator 106, and controls multiple signal components of the HF RF signal generator 106 based on the information to generate the RF signal 170. For example, the RF signal 170 is generated to have the power level and high frequency received within the recipe signal 168 from the processor 116. An example of the RF signal 170 is a sinusoidal signal, such as a sinusoidal waveform having multiple sine waves that repeat periodically.

The signal components of the LF RF pulse generator 104 send the square wave signal 166 via the output 136, the RF cable 138, and the input 140 to the HF filter 120. For example, the square wave signal 166 is received at the first end of the inductor of the HF filter 120. The HF filter 120 modifies an impedance of the square wave signal 166 to output a modified square wave signal 174 at its output. For example, the modified square wave signal 174 is output at the second end of the inductor of the HF filter 120. As an example, the modified square wave signal 174 is not a sinusoidal signal. The modified square wave signal 174 is sent from the output 142 via the RF connection 144 to the output connection 146.

Furthermore, the signal components of the HF RF signal generator 106 send the RF signal 170 via the output 132, the RF cable 154, and the input 156 to the match circuit 122. For example, the RF signal 170 is received at the first end of the branch circuit. The match circuit 122 matches an impedance of a load coupled to the output 158 with an impedance of a source coupled to the input 156 to output a modified RF signal 176 at the output 158. For example, the branch circuit matches the impedance of the load coupled to the output 158 with the impedance of the source coupled to the input 156 to modify an impedance of the RF signal 170 to provide the modified RF signal 176 at the second end of the branch circuit. An example of the load coupled to the output 158 includes a combination of the RF connection 160, the RF output connection 146, the RF transmission line 148, and the plasma chamber 112. An example of the source coupled to the input 156 includes a combination of the RF cable 154 and the HF RF signal generator 106. The modified RF signal 176 is sent from the output 158 via the RF connection 160 to the output connection 146.

A first portion of the modified RF signal 176 is combined, such as summed, with the modified square wave signal 174 at the output connection 146 to provide a combined signal 178 at the output connection 146. For example, an amplitude of the first portion of the modified RF signal 176 and an amplitude of the modified square wave signal 174 are summed at the output connection 146. As an example, the combined signal 178 is a square wave signal and not a sinusoidal signal.

In addition, a second portion 180 of the modified RF signal 176 is reflected from the output connection 146 via the RF connection 144 towards the HF filter 120. The second portion 180 has the high frequency. The HF filter 120 filters out the high frequency from the second portion 180 of the modified RF signal 176 to provide a reflected filtered signal 182 at the input 140. When the high frequency is filtered from the second portion 180, the reflected filtered signal 182 does not damage the signal components and the processor of the LF RF pulse generator 104. The reflected filtered signal 182 is reflected via the RF cable 138 towards the LF RF pulse generator 104.

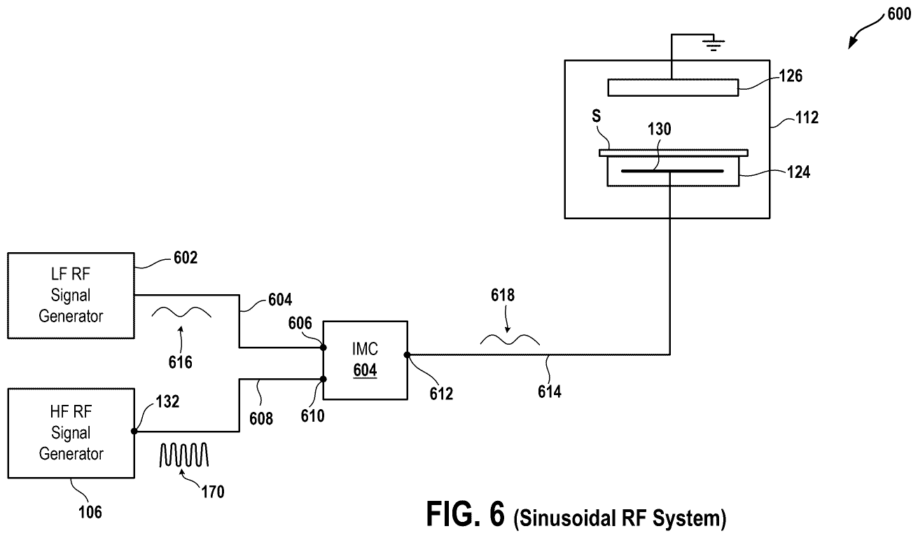

The combined signal 178 is sent via the RF rod of the RF transmission line 148 to the electrode 130. As an example, power of the combined signal 178 is represented as a square wave signal having power fluctuations of the high frequency of the first portion of the modified RF signal 176. When one or more process gases, such an oxygen containing gas, or a fluorine containing gas, or a combination thereof, are supplied to the gap 128 in addition providing the combined signal 178 to the electrode 130, plasma is stricken or maintained within the gap 128. The plasma is bordered by a top plasma sheath 129A and a bottom plasma sheath 129B. The plasma processes a substrate S, such as a semiconductor wafer, that is placed on the substrate support 124. Examples of processing the substrate S include etching the substrate S, depositing materials on the substrate S, and cleaning the substrate S. Use of the LF RF pulse generator 104 with the HF RF signal generator 106 facilitates faster frequency tuning of the HF RF signal generator 106 compared to when an LF RF signal generator (as shown in FIG. 6) is used with the HF RF signal generator 106.

In an embodiment, the terms RF ringing and RF voltage ringing are used herein interchangeably.

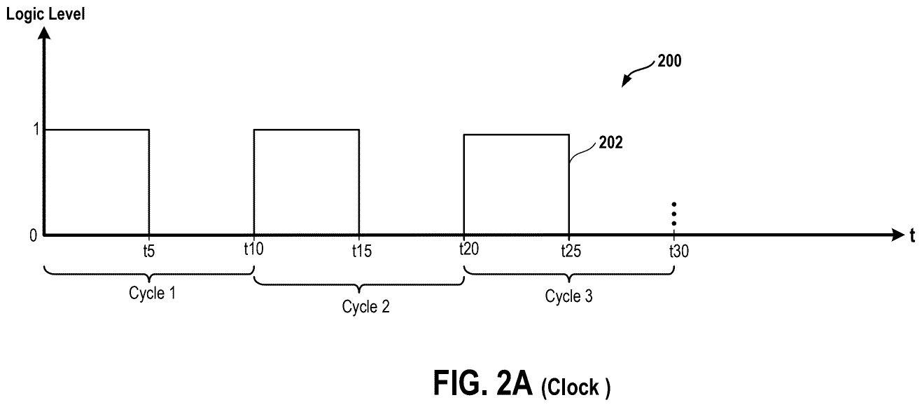

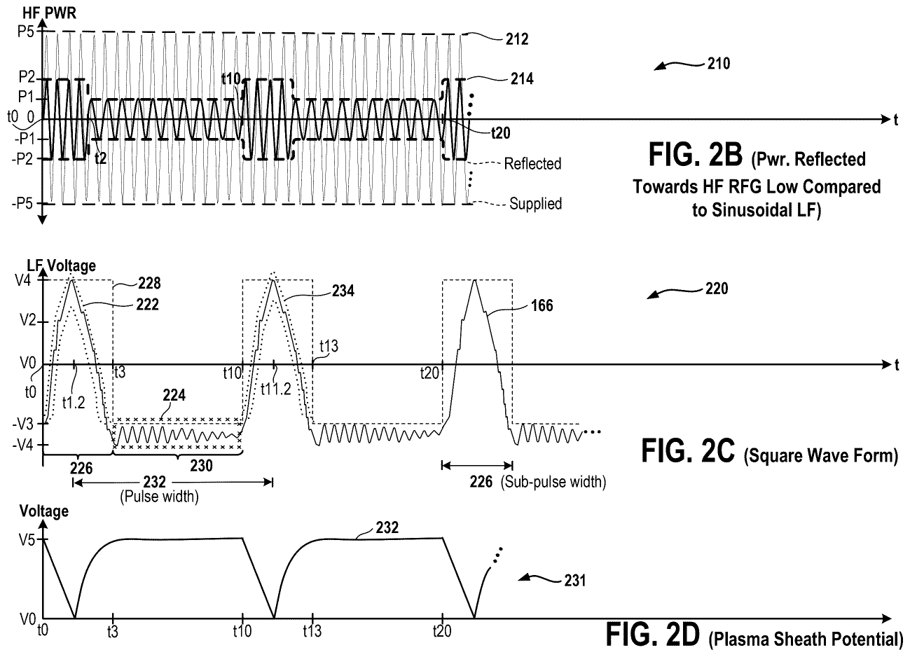

FIG. 2A is a graph 200 to illustrate an embodiment of a clock signal 202. The clock signal 202 is generated by the processor 116 (FIG. 1) and sent via the transfer cable 132 to the processor of the LF RF pulse generator 104 (FIG. 1). The processor of the LF RF pulse generator 104 controls the signal components of the LF RF pulse generator 104 in synchronization with the clock signal 202. Also, the clock signal 202 is sent via the transfer cable 150 (FIG. 1) to the processor of the HF RF signal generator 106 (FIG. 1). The processor of the HF RF signal generator 106 controls the signal components of the HF RF signal generator 106 in synchronization with the clock signal 202.

The graph 200 plots logic levels of the clock signal 202 versus time t. The logic levels are plotted on a y-axis of the graph 200 and the time t is plotted on an x-axis of the graph 200. The time t increases in a positive x-direction of the x-axis from a time t0 to a time t30. It should be noted that a time interval between two consecutive times on the x-axis of the graph 200 is equal to a time interval between any other two consecutive times on the x-axis. For example, a first time interval between the times t0 and t5 is equal to a second time interval between the times t5 and t10.

The clock signal 202 periodically transitions between a logic level 1 and a logic level 0. For example, during a cycle 1 of the clock signal 202, the clock signal 202 is at the logic level 1 from a time t0 to a time t5. Also, during the cycle 1, at the time t5, the clock signal 202 transitions from the logic level 1 to the logic level 0. Further, during the cycle 1, the clock signal 202 remains at the logic level 0 from the time t5 to the time t10. The logic levels 1 and 0 repeat in this manner during a cycle 2 of the clock signal 202 and during a cycle 3 of the clock signal 202.

FIG. 2B is a graph 210 to illustrate embodiments of high frequency supplied power and high frequency reflected power during each cycle of the clock signal 202 (FIG. 2A). The high frequency supplied power is forward power that is supplied by the HF RF signal generator 106 (FIG. 1) via the RF wire of the RF cable 154, the match circuit 122, the RF connection 160, the output connection 146, and the RF rod of the RF transmission line 148 to the electrode 130 (FIG. 1). The high frequency reflected power is power that is reflected from the plasma chamber 112 via the RF sheath of the RF transmission line 148, the output connection 146, the RF connection 160, a housing of the match circuit 122, and the RF sheath of the RF cable 154 towards the HF RF signal generator 106.

The graph 210 plots the high frequency supplied and reflected powers versus the time t. The high frequency supplied and reflected powers are plotted on a y-axis of the graph 210 and the time t is plotted on an x-axis of the graph 210. The powers plotted on the y-axis of the graph 210 range from a power amount −P5 to a power amount P5. The power amounts increase from the power amount −P5 to the power amount P5.

The high frequency supplied power has an envelope 212, which is a power level. The time t is the same as the time t of the graph 200 (FIG. 2A). As illustrated in FIG. 2A, the power level 212 is constant or substantially constant. For example, the power level 212 is at the power amount P5 from the time t0 to the time t30. To illustrate, the power level 212 is within a predetermined threshold, such as within ±10%, from the power amount P5.

Also, the high frequency reflected power has an envelope 214, which is a power level. The power level 214 is not constant during each cycle of the clock signal 202 (FIG. 2A). Rather, the power level 214 is at the power level P2 from the time t0 to the time t2 and transitions from the power amount P2 to the power amount P1 at the time t2. The power level 214 remains at the power amount P1 from the time t2 to the time t10. In this manner, the high frequency reflected power repeats periodically between the power levels P2 and P1 during each cycle of the clock signal 202.

The power sensor 135 (FIG. 1) measures high frequency delivered power of the RF signal 170 (FIG. 1) and sends the high frequency delivered power via the transfer cable 162 to the processor 116 (FIG. 1). The high frequency delivered power is embedded within a power signal 163 (FIG. 1). The processor 116 determines the high frequency reflected power as a difference between the high frequency supplied power and the high frequency delivered power received from the power sensor 135. The high frequency supplied power is accessed by the processor 116 from the memory device 118 (FIG. 1).

FIG. 2C is a graph 220 to illustrate a voltage of the square wave signal 166 that is generated by the LF RF pulse generator 104 (FIG. 1) versus the time t. The voltage of the square wave signal 166 is plotted on a y-axis of the graph 220 and the time t is plotted on an x-axis of the graph 220. The x-axis of the graph 220 is the same as the x-axis of the graph 210 (FIG. 2B). Voltage values of the square wave signal 166 range from −V4 to V4. The voltage values increase from −V4 to V4. For example, the voltage value −V3 is greater than the voltage value −V4 and the voltage value −V2 is greater than the voltage value −V3. Also, a difference between any two consecutive voltage values of the graph 220 is equal. For example, a difference between the voltage values −V3 and −V4 is equal to a difference between the voltage values −V2 and −V3.

The voltage of the square wave signal 166 has a sub-pulse 222 and RF voltage ringing 224 during the cycle 1. The sub-pulse 222 has a sub-pulse width 226, such as a time interval ranging from the time t0 to the time t3. At the time to, the sub-pulse 222 has the voltage value −V3 and at the time t3, the sub-pulse 222 has the voltage value −V3. The sub-pulse 222 has the voltage value −V3 at the time to and transitions up from the voltage value −V3 to the voltage value V4 during a time interval from the time t0 to the time t1.2. The sub-pulse 222 further transitions down from the voltage value V4 to the voltage value −V3 during a time interval from the time t1.2 to the time t3. The sub-pulse 222 is enclosed by an envelope 228, which is rectangular-shaped. By controlling the sub-pulse width 226, the envelope 228 becomes square-shaped. As an example, the sub-pulse width of any sub-pulse of the square wave signal 166 ranges from 10 nanoseconds (ns) to 500 ns and a rise time of each sub-pulse of the square wave signal 166 is about 50 ns. To illustrate, each sub-pulse of the square wave signal 166 has a rise time that ranges from 40 ns to 60 ns.

The sub-pulse 222 is immediately followed by the RF voltage ringing 224. The RF voltage ringing 224 has a ringing width 230, which is greater than the sub-pulse width 226. The RF voltage ringing 224 occurs during a time interval from the time t3 to the time t10. The RF voltage ringing 224 occurs during a greater time interval than the sub-pulse width 226 of the sub-pulse 222. The RF voltage ringing 224 is a series of micro pulses and each micro pulse has a smaller amplitude than an amplitude of the sub-pulse 222. For example, a maximum amplitude of the sub-pulse is V4 and a maximum amplitude of the RF voltage ringing 224 is −V3. Also, each micro pulse of the RF voltage ringing 224 has a smaller micro pulse width than the sub-pulse width 226 of the sub-pulse 222. An example of the micro pulse width is a time interval of occurrence of a micro pulse of the square wave signal 166. An example of an amplitude is a maximum amplitude or a peak-to-peak amplitude. In this manner, a sub-pulse and a series of micro pulses repeat periodically during each of the cycles 2 and 3.

It should be noted that, as an example, each sub-pulse of the square wave signal 166 has the same sub-pulse width 226 or substantially the same sub-pulse width. For example, the sub-pulse widths of the sub-pulses of the square wave signal 166 range within ±10% from each other. Also, the micro pulse width is outside the range of the sub-pulses of the square wave signal 166. For example, the micro pulse width is substantially less than the sub-pulse width of the voltage signal 137. As another example, the micro pulse width of the RF voltage ringing 224 reduces with a progression of the RF voltage ringing 224.

The square wave signal 166 also has a pulse width 232, which is a width between maximum amplitudes of two consecutive sub-pulses of the square wave signal 166. For example, the pulse width 232 is a time interval between the time t1.2 at which the sub-pulse 222 has the voltage value V4 and the time t11.2 at which a consecutive sub-pulse 234 has the voltage value V4.

It should be noted that the pulse width 232 represents a pulse width of the square wave signal 166 between any two consecutive ones of the cycles 1, 2, 3, and so on. For example, the pulse width 232 is of the square wave signal 166. In the example, the pulse width 232 remains substantially the same between any two consecutive ones of the cycles 1, 2, 3, and so on. To illustrate, the pulse width 232 between the cycles 2 and 1 is within ±10% from the pulse width 232 between the cycles 3 and 2.

The square wave signal 166 has the sub-pulse 234 and consecutively following RF voltage ringing during the cycle 2. The sub-pulse 234 has the voltage value V4, which is a peak value, such as a maximum amplitude, of the sub-pulse 234.

FIG. 2D is a graph 231 of an embodiment of a voltage signal 232 representing a voltage of the bottom plasma sheath 129B of the plasma. The voltage of the bottom plasma sheath 129B (FIG. 1) is plotted on a y-axis of the graph 231 and the time t is plotted on an x-axis of the graph 231. The x-axis of the graph 231 is the same as the x-axis of the graph 220. The voltage ranges from a voltage value V0 to a voltage value V5. The voltage values increase from V0 to V5.

During each cycle of the clock signal 202 (FIG. 2A), the voltage of the bottom plasma sheath 129B is substantially constant or is constant. For example, the voltage of the bottom plasma sheath 129B has the value V5 from the time t3 to the time 10. Also, the voltage of the bottom plasma sheath has the value V5 from the time t13 to the time 20. The constant or substantially constant voltage is achieved when the square wave signal 166 is generated to strike or maintain the plasma within the plasma chamber 112 (FIG. 1). As a result of the constant or the substantially constant voltage, a change in impedance of the plasma at the output 132 (FIG. 1) of the HF RF signal generator 106 is lower compared to when an LF RF signal is used to generate plasma within the plasma chamber 112. Therefore, the high frequency of the HF RF signal generator 104 (FIG. 1) is tuned more accurately and quickly when the square wave signal 166 is used compared to when the LF RF signal is used.

It takes less time to tune the HF RF signal generator 106 when the HF RF signal generator 106 is used with the LF RF pulse generator 104 (as shown in FIG. 1) compared to when the HF RF signal generator 106 is used with the LF RF signal generator (as shown in FIG. 6). For example, the processor 116 controls the HF RF signal generator 106 to generate the RF signal 170 having a frequency HF1. When the RF signal 170 has the frequency HF1, the processor 116 receives the power signal 163 from the power sensor 135 via the transfer cable 150 (FIG. 1). The power signal 163 indicates a first amount of the delivered power of the RF signal 170 at the output 132 (FIG. 1). Based on the first amount of delivered power and power supplied by the HF RF signal generator 106, the processor 116 calculates the high frequency reflected power of the RF signal 170 to be RP1. To illustrate, the processor 116 subtracts the first amount of delivered power from the power supplied by the HF RF signal generator 106 to calculate RP1. Continuing with the example, the processor 116 further controls the HF RF signal generator 106 to modify the frequency from HF1 to HF2 of the RF signal 170. When the RF signal 170 has the frequency HF2, the processor 116 receives the power signal 163 from the power sensor 135 via the transfer cable 150 and the power signal 163 indicates a second amount of the delivered power of the RF signal 170 at the output 132 (FIG. 1). Based on the second amount of delivered power and the power supplied by the HF RF signal generator 106, the processor 116 calculates the high frequency reflected power of the RF signal 170 to be RP2. To illustrate, the processor 116 subtracts the second amount of delivered power from the power supplied by the HF RF signal generator 106 to calculate RP2. The processor 116 determines that RP2 is less than RP1, and continues to control the HF RF signal generator 106 to operate at the frequency HF2. It should be noted that a time period between controlling the HF RF signal generator 106 to generate the RF signal 170 having the frequency HF1and determining that RP2 is less than RP1 is TP1.

Continuing with the example, instead of using the LF RF pulse generator 104, the LF RF signal generator (FIG. 6) and the HF RF signal generator 106 are coupled to the plasma chamber 112 via an impedance matching circuit (FIG. 6). When the LF RF signal generator (FIG. 6) and the HF RF signal generator 106 are coupled to the plasma chamber 112 via the impedance matching circuit (FIG. 6), the processor 116 controls the HF RF signal generator 106 to generate an HF RF signal (FIG. 6) having a frequency HF3. When the HF RF signal has the frequency HF3, the processor 116 receives the power signal 163 from the power sensor 135. The power signal 163 indicates a third amount of the delivered power of the RF signal 170 at the output 132. Based on the third amount of delivered power and power supplied by the HF RF signal generator 106, the processor 116 calculates the high frequency reflected power of the RF signal 170 to be RP3. To illustrate, the processor 116 subtracts the third amount of delivered power from the power supplied by the HF RF signal generator 106 to calculate RP3. Continuing with the example, the processor 116 further controls the HF RF signal generator 106 to modify the frequency from HF3 to HF4 of the HF RF signal. When the HF RF signal has the frequency HF4, the processor 116 receives the power signal 163 from the power sensor 135 via the transfer cable 150 and the power signal 163 indicates a fourth amount of power of the delivered power of the RF signal 170 at the output 132. Based on the fourth amount of delivered power and the power supplied by the HF RF signal generator 106, the processor 116 calculates the high frequency reflected power of the RF signal 170 to be RP4. To illustrate, the processor 116 subtracts the fourth amount of delivered power from the power supplied by the HF RF signal generator 106 to calculate RP4. The processor 116 determines that RP4 is less than RP3, and continues to control the HF RF signal generator 106 to operate at the frequency HF4. It should be noted that a time period between controlling the HF RF signal generator 106 to generate the HF RF signal having the frequency HF3 and determining that RP4 is less than RP3 is TP2. Also, TP2 is greater than TP1, and RP2 is less than RP4. Because RP2 is less than RP4, the HF RF signal generator 106 used with the LF RF pulse generator 104 is tuned more accurately compared to when the HF RF signal generator 106 is used with the LF RF signal generator (FIG. 6). Also, because TP2 is greater than TP1, the time period of tuning the high frequency of the HF RF signal generator 104 is greater when the HF RF signal generator 106 is used with the LF RF signal generator (FIG. 6).

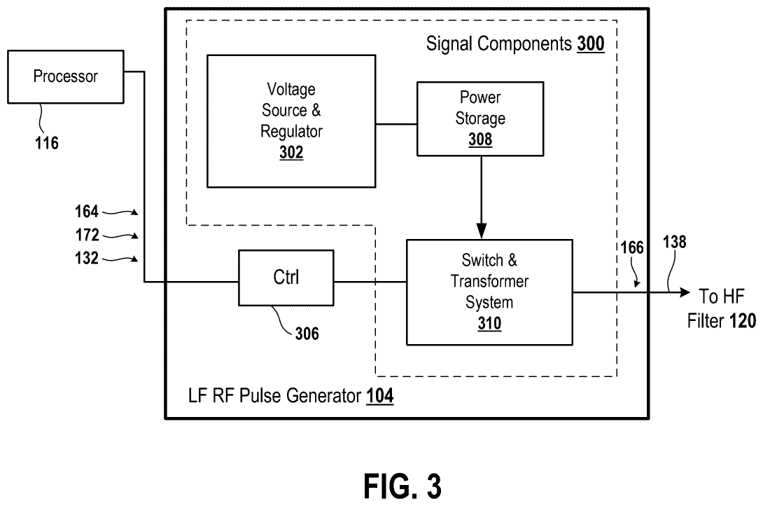

FIG. 3 is an embodiment of the LF RF pulse generator 104. The LF RF pulse generator 104 includes signal components 300 and a controller 306. The signal components 300 include a voltage and source regulator 302, a power storage 308, and a switch and transformer system 310. As an example, RF voltage ringing, as described herein, is noise due to one or more of the signal components 300.

An example of the voltage source and regulator 302 includes a combination of a voltage supply, such as a direct current (DC) voltage supply, and a voltage regulator, such as a variable resistor. The voltage supply is coupled to the voltage regulator. An example of the switch and transformer system 310 includes a combination of a switch, such as a solid-state switch, and a transformer. An illustration of the solid-state switch is a transistor or a group of transistors. The solid-state switch is coupled to the transformer. As an example, the transformer includes a primary winding and a secondary winding. An example of the power storage 308 includes a capacitor.

An example of the controller 306 includes the processor and the memory device. The processor of the controller 306 is coupled to the memory device of the controller 306. As another example, the controller 306 is an ASIC or a PLD.

The processor 116 is coupled to the processor of the controller 306 via the transfer cable 132. The processor of the controller 306 is coupled to the switch of the switch and transformer system 310. The voltage regulator of the voltage source and regulator 302 is coupled to the power storage 308.

Moreover, the power storage 308 is coupled to the transformer and the switch is coupled to the transformer. For example, the power storage 308 is coupled to a first end of the primary winding and the switch is coupled to a second end of the primary winding. The secondary winding of the transformer is coupled to the RF cable 138.

Upon receiving the information within the recipe signal 164, the processor of the controller 306 stores the information within the memory device of the controller 306. The voltage supply generates a voltage signal and supplies the voltage signal to the voltage regulator. The voltage regulator regulates the voltage signal, such as maintains the voltage signal to match a pre-determined voltage signal, to output a regulated voltage signal, and sends the regulated voltage signal to the power storage 308. The power storage 308 stores a charge according to the regulated voltage signal.

Moreover, in response to receiving the trigger signal 172, such as at the time to, the processor of the controller 306 accesses the sub-pulse width 226 (FIG. 2C) of the square wave signal 166 (FIG. 1) from the memory device of the controller 306, generates an on command signal, and sends the on command signal to the switch. When the on command signal is received, the switch turns on and a switch current signal generated to discharge the charge stored in the power storage 308 is supplied to the primary winding of the transformer for the time period of the sub-pulse width 226. The secondary winding transforms, such as increases or decreases, an amount of voltage of the switch current signal to a different amount to output a transformed amount of voltage to start generating the sub-pulse 222 (FIG. 2C). The transformed amount of voltage is a voltage of the sub-pulse 222.

At the end of the time period of the sub-pulse width 226, the processor of the controller 306 generates an off command signal, and sends the off command signal to the switch. Upon receiving the off command signal, the switch turns off and the supply of the switch current signal to the primary winding stops. When the supply of the switch current signal stops, the voltage applied by the switch current signal drops to reduce the voltage across the primary winding. When the voltage across the primary winding reduces, the transformed amount of voltage reduces to end the generation of the sub-pulse 222 to output a reduced transformed amount of voltage. The reduced transformed amount of voltage is of the RF voltage ringing 230 (FIG. 2C).

The processor of the controller 306 controls the switch to be off until an end of the cycle 1 of the clock signal 202 (FIG. 2A). After the end of the cycle 1 and at a beginning of the cycle 2, the processor of the controller 306 controls the switch to be turned back on for the time period of the sub-pulse width 226 to generate the sub-pulse 234. In this manner, multiple sub-pulses and multiple RF voltage ringings of the square wave signal 166 are generated.

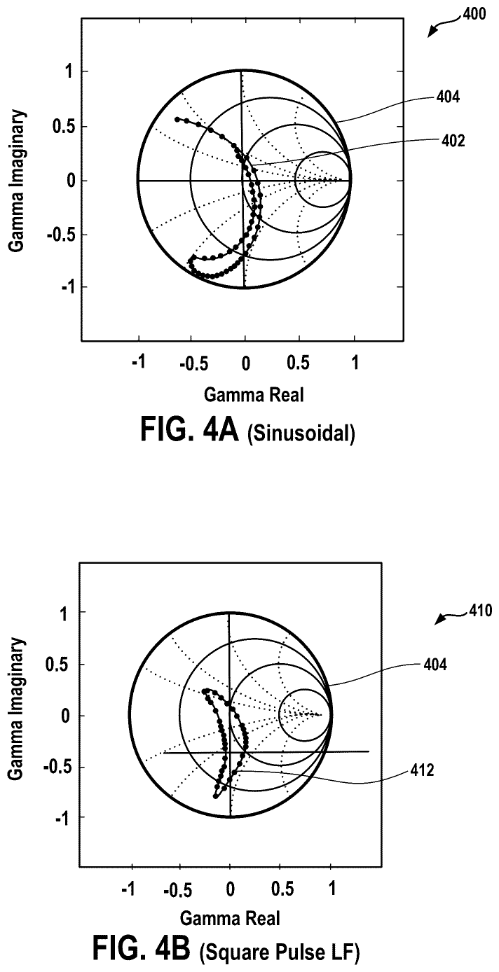

FIG. 4A is a graph 400 to illustrate that a greater amount of power is reflected towards the HF RF signal generator 106 (FIG. 1) when the LF RF signal generator (FIG. 6) is used compared to when the LF RF pulse generator 104 (FIG. 1) is used. The graph 400 includes of a plot 402 of an imaginary portion of a voltage reflection coefficient (gamma or I) versus a real portion of the voltage reflection coefficient. As shown in the graph 400, a first number of values of the plot 402 are close to a magnitude of gamma of 1, which represents an edge 404 of a circle.

FIG. 4B is a graph 410 to illustrate that a lesser amount of power is reflected towards the HF RF signal generator 106 (FIG. 1) when the LF RF pulse generator 104 (FIG. 1) is used compared to when the LF RF signal generator (FIG. 6) is used. The graph 410 includes of a plot 412 of an imaginary portion of the voltage reflection coefficient versus a real portion of the voltage reflection coefficient. As shown in the graph 410, a second number of values of the plot 412 are close to the magnitude of gamma of 1. It should be noted that the second number is less than the first number.

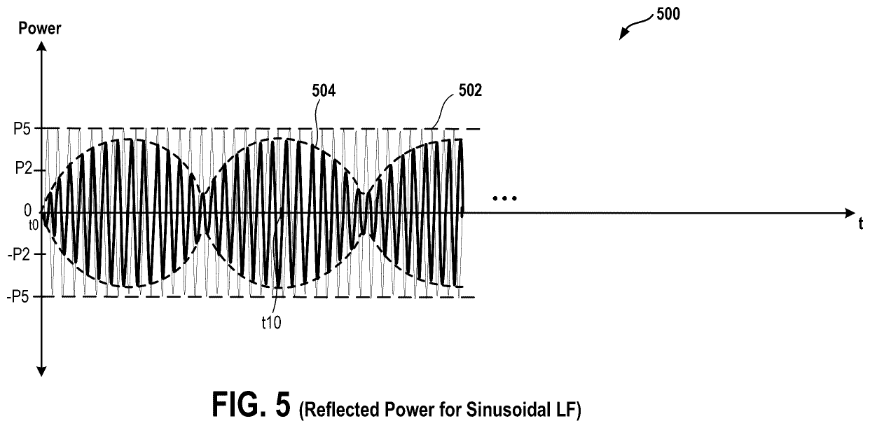

FIG. 5 is a graph 500 to illustrate forward and reflected powers of the LF RF signal (FIG. 6). The graph 500 plots the forward and reflected powers of the LF RF signal versus the time t. The forward and reflected powers of the LF RF signal are plotted on a y-axis of the graph 500 and the time t is plotted on an x-axis of the graph 500. The x-axis of the graph 500 is the same as the x-axis of the graph 210 (FIG. 2B). The graph 500 includes an envelope 502 of the forward power of the LF RF signal and includes an envelope 504 of the reflected power of the LF RF signal. An example of an envelope is a power level. The forward and reflected powers of the LF RF signal range from a power value −P5 to a power value P5. The power values increase from −P5 to P5.

The forward power plotted in the graph 500 is power supplied by the LF RF signal generator (FIG. 6) and the reflected power is power reflected towards the LF RF signal generator (FIG. 6). Comparing the graph 210 with the graph 500, it should be noted that an amount of power reflected towards the HF RF signal generator 106 (FIG. 1) is greater when the LF RF signal generator (FIG. 6) is used instead of the LF RF pulse generator 104 (FIG. 1).

FIG. 6 is a diagram of an embodiment of a system 600 to illustrate use of the HF RF signal generator 106 with an LF RF signal generator 602 and to illustrate that the rate of processing the substrate S increases when the LF RF pulse generator 104 (FIG. 1) is used. The system 600 includes the LF RF signal generator 602, the HF RF signal generator 106, an impedance matching circuit (IMC) 604, and the plasma chamber 112. The LF RF signal generator 602 operates at the low frequency.

The LF RF signal generator 602 is coupled via an RF cable 604 to an input 606 of the IMC 604. As an example, the RF cable 604 lacks a capacity to handle voltage of the square wave signal 104 (FIG. 1). To illustrate, the RF cable ruptures when the square wave signal 104 passes through it. To further illustrate, a maximum amplitude of the square wave signal 104 is greater than a maximum amplitude of an RF signal 616 generated by the LF RF signal generator 602. Also, the HF RF generator 602 is coupled via an RF cable 608 to an input 610 of the IMC 604. An output 612 of the IMC 604 is coupled via an RF transmission line 614 to the electrode 130.

The LF RF signal generator 602 generates the RF signal 616, which is a sinusoidal signal, and sends the RF signal 616 via the RF cable 604 and the input 606 to the IMC 604. Also, the HF RF signal generator 106 generates the RF signal 170 and sends the RF signal 170 via the RF cable 608 and the input 610 to the IMC 604.

The IMC 604 includes a first circuit between the input 606 and the output 612 and a second circuit between the input 610 and the output 612. The first circuit modifies an impedance of a load coupled to the output 612 with an impedance of a source coupled to the input 606 to output a first modified signal, which is a sinusoidal signal. An example of the load coupled to the output 612 includes a combination of the RF transmission line 614 and the plasma chamber 112. An example of the source coupled to the input 606 includes a combination of the RF cable 604 and the LF RF signal generator 602.

Also, the second circuit modifies an impedance of the load coupled to the output 612 with an impedance of a source coupled to the input 610 to output a second modified signal, which is a sinusoidal signal. An example of the source coupled to the input 610 includes a combination of the RF cable 608 and the HF RF signal generator 106. The first and second modified signals are summed in the IMC 604 to output a modified signal 618, which is sent from the output 612 to the electrode 130 for processing the substrate S. The modified signal 618 is a sinusoidal signal and not a square wave signal.

It should be noted that because the RF signal 616 is supplied with the RF signal 170, a greater amount of power is reflected towards the HF RF generator 106 from the plasma chamber 112 compared to that reflected when the square wave signal 166 is used with the RF signal 170. Because of the high amount of high frequency reflected power, the substrate S is processed in a less efficient manner.

Embodiments described herein may be practiced with various computer system configurations including hand-held hardware units, microprocessor systems, microprocessor-based or programmable consumer electronics, minicomputers, mainframe computers and the like. The embodiments can also be practiced in distributed computing environments where tasks are performed by remote processing hardware units that are linked through a network.

In some embodiments, a controller is part of a system, which may be part of the above-described examples. Such systems include semiconductor processing equipment, including a processing tool or tools, chamber or chambers, a platform or platforms for processing, and/or specific processing components (a wafer pedestal, a gas flow system, etc.). These systems are integrated with electronics for controlling their operation before, during, and after processing of a semiconductor wafer or substrate. The electronics is referred to as the “controller,” which may control various components or subparts of the system or systems. The controller, depending on the processing requirements and/or the type of system, is programmed to control any of the processes disclosed herein, including the delivery of process gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks coupled to or interfaced with a system.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

The controller, in some embodiments, is a part of or coupled to a computer that is integrated with, coupled to the system, otherwise networked to the system, or a combination thereof. For example, the controller is in a “cloud” or all or a part of a fab host computer system, which allows for remote access of the wafer processing. The computer enables remote access to the system to monitor current progress of fabrication operations, examines a history of past fabrication operations, examines trends or performance metrics from a plurality of fabrication operations, to change parameters of current processing, to set processing steps to follow a current processing, or to start a new process.

In some embodiments, a remote computer (e.g. a server) provides process recipes to a system over a network, which includes a local network or the Internet. The remote computer includes a user interface that enables entry or programming of parameters and/or settings, which are then communicated to the system from the remote computer. In some examples, the controller receives instructions in the form of data, which specify the parameters, factors, and/or variables for each of the processing steps to be performed during one or more operations. It should be understood that the parameters, factors, and/or variables are specific to the type of process to be performed and the type of tool that the controller is configured to interface with or control. Thus as described above, the controller is distributed, such as by including one or more discrete controllers that are networked together and working towards a common purpose, such as the processes and controls described herein. An example of a distributed controller for such purposes includes one or more integrated circuits on a chamber in communication with one or more integrated circuits located remotely (such as at the platform level or as part of a remote computer) that combine to control a process on the chamber.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

As noted above, depending on the process step or steps to be performed by the tool, the host computer communicates with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

With the above embodiments in mind, it should be understood that some of the embodiments employ various computer-implemented operations involving data stored in computer systems. These operations are those physically manipulating physical quantities. Any of the operations described herein that form part of the embodiments are useful machine operations.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

In some embodiments, the operations may be processed by a computer selectively activated or configured by one or more computer programs stored in a computer memory, cache, or obtained over the computer network. When data is obtained over the computer network, the data may be processed by other computers on the computer network, e.g., a cloud of computing resources.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment, described above, are combined with one or more features of any other embodiment, also described above, without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A method for increasing a rate of processing a substrate using a square wave signal, comprising:
generating, by a low frequency (LF) radio frequency (RF) pulse generator, the square wave signal;
generating, by a high frequency (HF) RF signal generator, a sinusoidal RF signal;
supplying the square wave signal to a filter coupled to an electrode of a plasma chamber;
supplying the sinusoidal RF signal to an impedance matching circuit that is coupled to the electrode, wherein said supplying the square wave signal reduces power reflected towards the HF RF signal generator from the plasma chamber, wherein a reduction in the power reflected towards the HF RF signal generator increases the rate of processing the substrate.

2. The method of claim 1, wherein the power is reduced compared to power reflected towards the HF RF signal generator from the plasma chamber when the HF RF signal generator is used with an LF RF signal generator, wherein the LF RF signal generator is used with the HF RF signal generator instead of the LF RF pulse generator.

3. The method of claim 1, further comprising:
modifying an impedance of the square wave signal to output a modified square wave signal;
modifying an impedance of the sinusoidal RF signal to output a modified RF signal;
combining the modified square wave signal with the modified RF signal to output a combined signal;
providing the combined signal to the electrode.

4. The method of claim 1, wherein the square wave signal has a kilohertz (kHz) radio frequency and the sinusoidal RF signal has a megahertz (MHz) radio frequency, the method further comprising filtering by the filter, the MHz radio frequency from a reflected RF signal of the MHz radio frequency to output a filtered signal towards the LF RF pulse generator.

5. The method of claim 1, wherein the square wave signal includes a sub-pulse followed by a plurality of pulses during each of a plurality of clock cycles of a clock signal, wherein the plurality of pulses has a smaller peak-to-peak amplitude than a peak-to-peak amplitude of the sub-pulse, wherein the square wave signal has a kilohertz (kHz) radio frequency, wherein the kHz RF is a frequency of repetition of a plurality of peak values of a plurality of sub-pulses of the square wave signal over the plurality of clock cycles.

6. The method of claim 1, wherein the square wave signal is a nonsinusoidal signal.

7. The method of claim 6, wherein the nonsinusoidal signal includes a sub-pulse followed by a plurality of pulses during each of a plurality of clock cycles of a clock signal, wherein the plurality of pulses has a smaller peak-to-peak amplitude than a peak-to-peak amplitude of the sub-pulse.

8. The method of claim 1, wherein the filter is not an impedance matching circuit, wherein the square wave signal has a kilohertz (kHz) radio frequency and the sinusoidal RF signal has a megahertz (MHz) radio frequency.

9. The method of claim 8, wherein the kHz frequency ranges from 10 kHz to 800 kHz.

10. A controller for increasing a rate of processing a substrate using a square wave signal, comprising:
a processor configured to control a low frequency (LF) radio frequency (RF) pulse generator to generate the square wave signal and supply the square wave signal to a filter, wherein the filter is coupled to an electrode of a plasma chamber,
wherein the processor is configured to control a high frequency (HF) RF signal generator to generate a sinusoidal RF signal and supply the sinusoidal RF signal to an impedance matching circuit, wherein the impedance matching circuit is coupled to the electrode,
wherein the LF RF pulse generator is controlled to reduce power reflected towards the HF RF signal generator from the plasma chamber, wherein a reduction in the power reflected towards the HF RF signal generator increases the rate of processing the substrate; and
a memory device coupled to the processor.

11. The controller of claim 10, wherein the power is reduced compared to power reflected towards the HF RF signal generator from the plasma chamber when the HF RF signal generator is used with an LF RF signal generator, wherein the LF RF signal generator is used with the HF RF signal generator instead of the LF RF pulse generator.

12. The controller of claim 10, further comprising:
wherein the filter is configured to modify an impedance of the square wave signal to output a modified square wave signal,
wherein the impedance matching circuit is configured to modify an impedance of the sinusoidal RF signal to output a modified RF signal,
wherein the filter is coupled to the electrode via a first RF connection and an output connection, wherein the impedance matching circuit is coupled to the electrode via a second RF connection and the output connection,
wherein the output connection is configured to combine the modified square wave signal with the modified RF signal to output a combined signal,
wherein the output connection is configured to transfer the combined signal to the electrode.

13. The controller of claim 10, wherein the square wave signal has a kilohertz (kHz) radio frequency and the sinusoidal RF signal has a megahertz (MHz) radio frequency, wherein the filter is configured to filter the MHz radio frequency from a reflected RF signal of the MHz radio frequency to output a filtered signal towards the LF RF pulse generator.

14. The controller of claim 10, wherein the square wave signal includes a sub-pulse followed by a plurality of pulses during each of a plurality of clock cycles of a clock signal, wherein the plurality of pulses has a smaller peak-to-peak amplitude than a peak-to-peak amplitude of the sub-pulse, wherein the square wave signal has a kilohertz (kHz) radio frequency, wherein the kHz RF is a frequency of repetition of a plurality of peak values of a plurality of sub-pulses of the square wave signal over the plurality of clock cycles.

15. The controller of claim 10, wherein the square wave signal is a nonsinusoidal signal, wherein the nonsinusoidal signal includes a sub-pulse followed by a plurality of pulses during each of a plurality of clock cycles of a clock signal, wherein the plurality of pulses has a smaller peak-to-peak amplitude than a peak-to-peak amplitude of the sub-pulse.

16. The controller of claim 10, wherein the filter is not an impedance matching circuit, wherein the square wave signal has a kilohertz (kHz) radio frequency and the sinusoidal RF signal has a megahertz (MHz) radio frequency.

17. The controller of claim 16, wherein the kHz frequency ranges from 50 kHz to 800 kHz.

18. A system for increasing a rate of processing a substrate using a square wave signal, comprising:
a low frequency (LF) radio frequency (RF) pulse generator configured to generate the square wave signal;
a high frequency (HF) RF signal generator configured to generate a sinusoidal RF signal;
a filter coupled to the LF RF pulse generator to receive the square wave signal;
a plasma chamber having an electrode coupled to the filter;
an impedance matching circuit between the HF RF signal generator and the electrode of the plasma chamber, wherein the impedance matching circuit is configured to receive the sinusoidal RF signal,
wherein the LF RF pulse generator is configured to reduce power reflected towards the HF RF signal generator from the plasma chamber, wherein a reduction in the power reflected towards the HF RF signal generator increases the rate of processing the substrate.

19. The system of claim 18, wherein the power is reduced compared to power reflected towards the HF RF signal generator from the plasma chamber when the HF RF signal generator is used with an LF RF signal generator, wherein the LF RF signal generator is used with the HF RF signal generator instead of the LF RF pulse generator.

20. The system of claim 18,
wherein the filter is configured to modify an impedance of the square wave signal to output a modified square wave signal,
wherein the impedance matching circuit is configured to modify an impedance of the sinusoidal RF signal to output a modified RF signal,
wherein the filter is coupled to the electrode via a first RF connection and an output connection, wherein the impedance matching circuit is coupled to the electrode via a second RF connection and the output connection,
wherein the output connection is configured to combine the modified square wave signal with the modified RF signal to output a combined signal,
wherein the output connection is configured to transfer the combined signal to the electrode.
